(19) United States
(12) Patent Application Publication
(10) Pub. No.: US 2023/0010064 A1
(43) Pub. Date: Jan. 12, 2023

(54) CIRCUIT BOARD AND METHODS FOR FABRICATING A CIRCUIT BOARD

(71) Applicant: The University of British Columbia, Vancouver (CA)

(72) Inventors: Mirza Sarwar, Vancouver (CA); Sylvester Zhang, Vancouver (CA); John Madden, Vancouver (CA)

(21) Appl. No.: 17/779,525

(22) PCT Filed: Sep. 17, 2020
(86) PCT No.: PCT/CA2020/051250

§ 371 Date: May 24, 2022

Related U.S. Application Data
(60) Provisional application No. 62/951,603, filed on Dec. 20, 2019.

(51) Int. Cl. H05K 1/02; H05K 3/00; H05K 1/03; H05K 3/18; H05K 1/09; H05K 3/46; C09D 11/033; C09D 1/00; C23C 18/38; C23C 18/16; C23C 28/02; C25D 5/56; C25D 3/38

(52) U.S. Cl. CPC H05K 1/0283; H05K 3/0014; H05K 1/032; H05K 3/188; H05K 1/092; H05K 3/4611; C09D 11/033; C09D 1/00; C23C 18/38; C23C 18/1689; C23C 18/1641; C23C 18/1653; C23C 28/023; C25D 5/56; C25D 3/38

(57) ABSTRACT

A method for fabricating a circuit board comprises preparing an elastomeric substrate having a roughened surface. The elastomeric substrate is stretched before an electrically conductive material is electrolessly deposited onto the roughened surface. A suitable amount of electrically conductive material is deposited onto the elastomeric substrate before the elastomeric substrate is released from its stretch.

### CROSS-REFERENCE TO RELATED APPLICATIONS

This application claims priority from U.S. Application No. 62/951,603 filed 20 Dec. 2019. For purposes of the United States, this application claims the benefit under 35 U.S.C. § 119 of U.S. Application No. 62/951,603 filed 20 Dec. 2019 and entitled STRETCHABLE PRINTED CIRCUIT BOARD which is hereby incorporated herein by reference for all purposes.

### TECHNICAL FIELD

This invention relates to circuit boards, and in particular to stretchable and/or flexible circuit boards and methods for fabricating circuit boards which are flexible and/or stretchable.

### BACKGROUND

Wearable technologies include functional electronic devices that are embedded or otherwise integrated into clothing or other wearable items such as patches, watches, etc. There is a need for wearable technologies which provide electronic circuits in parts of wearables that are flexible. To facilitate such technologies there is a need for printed circuit boards (PCBs) that are bendable (i.e. flexible) about one or more axes. Such PCBs would allow wearables that provide electronic functionality to conform to the contours of various parts of the human body. In some cases it would be beneficial to have PCBs that are stretchable. For example, in some applications it would be beneficial to provide PCBs that are sufficiently stretchable to stretch with a person's skin. For example it might be desirable to provide a flexible and/or stretchable circuit board that supports one or more sensors adjacent to a person's skin.

A problem with some PCBs is that they are not sufficiently flexible. Another problem is that flexible PCBs can be costly to fabricate. Another problem is that many PCBs that are flexible are not also stretchable to a desired degree in one or more directions.

There remains a need for methods for fabricating PCBs which have one or more of: improved flexibility, improved stretchability, and improved electrical reliability under stretch and/or flex. There also remains a need for cost-effective PCBs which possess such properties.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

Aspects of the invention include without limitation:
circuit boards which are flexible and/or stretchable;
methods for fabricating a flexible and/or stretchable circuit boards.

One aspect of the invention relates to a method for fabricating circuit boards. The method comprises providing a substrate made of an elastomeric material having a roughened surface. The substrate is then stretched and held in a stretched state. The substrate's surface energy is increased by applying a surface treatment to the roughened surface of the substrate. A catalyst is deposited on the roughened surface of the substrate. A first layer of electrically conductive material is deposited on the roughened surface of the substrate by electroless deposition. A second layer of electrically conductive material is deposited on the first layer of electrically conductive material. After the electrically conductive materials are deposited on the substrate, the substrate is released from its stretched state.

In some embodiments, providing the elastomeric substrate comprises dissolving styrene-ethelyne-butylene-styrene (SEBS) in a solvent to produce an elastomer solution, followed by spreading the elastomer solution over a coarse surface, and evaporating the solvent from the elastomer solution to form the elastomeric substrate. The elastomer solution may, for example, have a concentration in the range of 35% w/w to 45% w/w.

In some embodiments, providing the polymeric substrate comprises pressing styrene-ethelyne-butylene-styrene (SEBS) between first and second heated plates. The SEBS may be provided in the form of pellets.

In some embodiments, the elastomeric substrate is stretched by at least 10% in a longitudinal direction.

In some embodiments, the surface treatment applied to the substrate comprises plasma treating the roughened surface of the substrate. The water contact angle on the roughened surface may be less than 47 degrees after surface treatment.

In some embodiments, depositing the catalyst on the roughened surface of the substrate comprises applying a catalyst to the roughened surface of the substrate and reducing the catalyst on the substrate to yield particles of the catalyst on the roughened surface of the substrate. The catalyst may be applied in a catalyst solution. The catalyst solution may be a silver ink. The silver ink may comprise a solvent selected from ethanol, ethylene glycol and a mixture of ethanol and ethylene glycol. The ink may comprise silver nitrate dissolved in a mixture of ethanol and ethylene glycol. The silver ink may, for example, comprise a solution of silver nitrate having a concentration in the range of 15 to 26 nM.

In some embodiments, reducing the catalyst comprises exposing the catalyst to an air plasma. The catalyst may be exposed to the air plasma at a pressure in the range of 300 to 800 mbar. The catalyst may be exposed to the air plasma for at least 15 minutes.

In some embodiments, the electroless deposition solution comprises a cupric sulfate solution. The cupric sulfate solution may comprise sodium potassium tartrate and formaldehyde. The electroless deposition solution may comprise a potassium tartrate solution, the cupric sulfate solution, and a formaldehyde solution in a ratio of 1:1:1. In some embodiments, the substrate is immersed in the electroless deposition solution for a period of 15 minutes or less. In some embodiments, the substrate is rinsed in deionized water after removing the substrate from the electroless deposition solution.

In some embodiments, the substrate is heated under an inert gas atmosphere after electrodepositing the second layer of electrically conductive material. In some embodiments, the first and second layers of electrically conductive material are patterned. The first and second layers of electrically conductive material may be patterned to create electrically conductive traces which are arranged in a serpentine shape. The electrically conductive traces may be arranged in the serpentine shape to meander along a direction in which the substrate is stretched. In some embodiments, one or more via holes are created on the substrate before stretching the substrate.

Another aspect of the invention relates to a method for fabricating a multi-layered circuit board. The method comprises fabricating a plurality of stretchable single-layered circuit boards using methods described herein and subsequently bonding the plurality of single-layered circuit boards together to create the multi-layered circuit board. In some embodiments, the multi-layered circuit board is encapsulated in a resin.

In addition to the exemplary aspects and embodiments described above, further aspects and embodiments will become apparent by reference to the drawings and by study of the following detailed descriptions.

### BRIEF DESCRIPTION OF THE DRAWINGS

Exemplary embodiments are illustrated in referenced figures of the drawings. It is intended that the embodiments and figures disclosed herein are to be considered illustrative rather than restrictive.

FIG. 1 is a flowchart that illustrates a method of fabricating a circuit board according to an example embodiment of the invention. FIG. 1A is a flowchart that illustrates a process that applies the FIG. 1 method to fabricate a styrene-ethylene-butylene-styrene (SEBS) circuit board.

FIG. 2 is a flowchart that illustrates a process for fabricating a multi-layered circuit board according to an example embodiment of the invention.

FIG. 3 is a schematic perspective view of an exemplary pre-patterned circuit board as may be fabricated using the method shown in FIG. 1. FIG. 3A is a schematic perspective view of a section of an exemplary patterned circuit board as may be fabricated using the method shown in FIG. 1.

### DETAILED DESCRIPTION

Throughout the following description specific details are set forth in order to provide a more thorough understanding to persons skilled in the art. However, well known elements may not have been shown or described in detail to avoid unnecessarily obscuring the disclosure. Accordingly, the description and drawings are to be regarded in an illustrative, rather than a restrictive, sense.

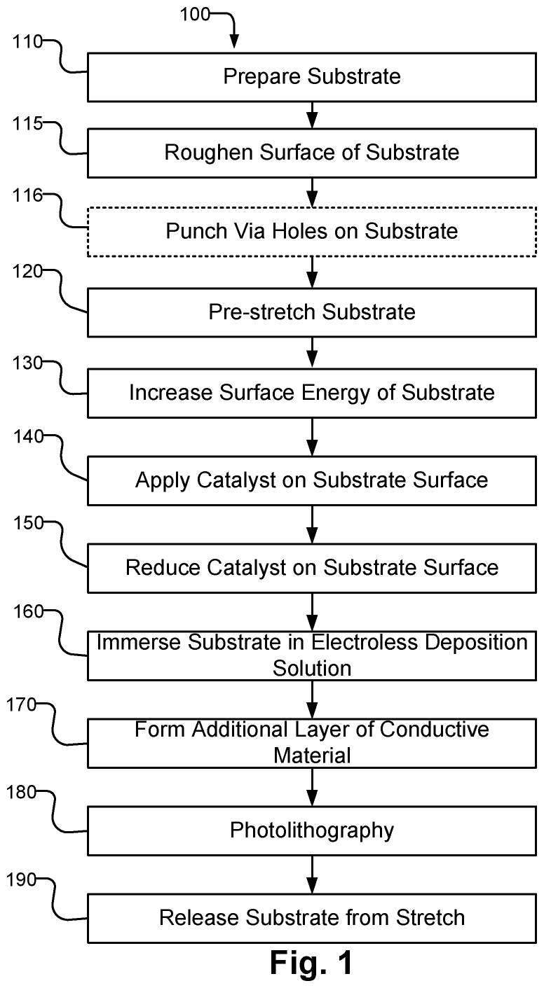

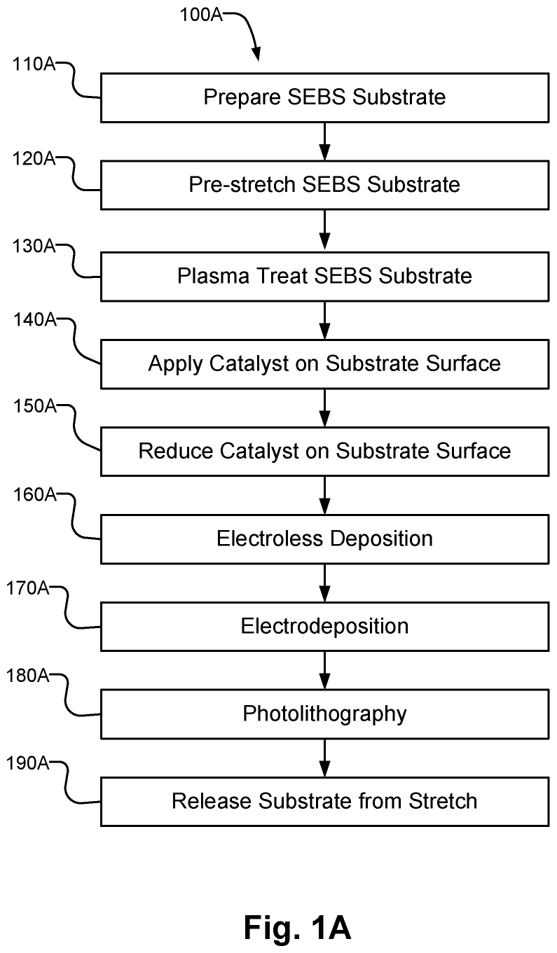

One aspect of this invention provides methods for making circuit boards. FIG. 1 is a flowchart depicting a method 100 for fabricating a circuit board according to an example embodiment of the invention.

In block 110 an elastomeric substrate is prepared or provided. For the purposes of facilitating the description, an elastomeric substrate described herein refers to a substrate made of a polymeric material having a modulus of elasticity which is low enough to allow the substrate to stretch (e.g. by at least more than about 0.5% or 1% or 2% or 5%) without undergoing plastic deformation. In some embodiments the substrate has a modulus of elasticity and cross sectional area selected such that when the substrate is stretched in a longitudinal direction by a force of 0.2N per centimeter of transverse width of the substrate then the substrate will stretch by at least 1% in the longitudinal direction.

Examples of suitable polymeric materials include but are not limited to: styrene-containing copolymers such as styrene-ethylene-butylene-styrene (SEBS) or Poly(Styrene-block-IsoButylene-block-Styrene) (SIBS), copolymers containing heteroatoms such as polyurethane (PU), thermoplastic polymers having elasticity approaching that of rubber, hydrogenated polymers, etc.

In some embodiments, the polymeric material has a composition of at least 15% styrene by weight. In some embodiments, the polymeric material consists essentially of styerenic chains and aliphatic chains. In some embodiments the polymeric material contains in the range of about 15% to about 50% styrene and the remainder is aliphatic chains such as ethylene or butylene. In some embodiments the polymeric material is substantially free of polyurethane (e.g. has less than 3% or 1% or 0.5% or 0.1% polyurethane).

In some embodiments, the elastomeric substrate provided in block 110 has a modulus of elasticity which is below about 10 GPa. In some embodiments, the elastomeric substrate prepared in block 110 has a flexural modulus which is below about 5 GPa. In some embodiments, the elastomeric substrate prepared in block 110 has a surface which is soft enough to allow the elastomeric substrate to be strained without overstraining the conductive traces deposited on top of the elastomeric substrate but not too soft to cause poor adhesion of the conductive traces.

A suitable grade of SEBS can be advantageously used as a substrate for a PCB. SEBS can be highly resistant to degradation by UV light, can be formulated to have a hardness selected within a wide range, can be formulated to be elastic, can be formulated to be flexible, and can have good dielectric (i.e. sufficient electrical insulation) properties. However, to successfully use SEBS or other similar materials as a substrate for a PCB it is necessary to have some way to form electrically conductive traces on the substrate. The present methods facilitate forming electrically conductive layers on substrates made of SEBS and similar materials.

In some embodiments, the substrate is prepared in block 110 by solvent casting an elastomer, for example SEBS. In these embodiments, an elastomer solute is dissolved in a solvent such as toluene to form an elastomer solution. The solution has a concentration which is typically in the range of 30% to 60% w/w (i.e. the solution typically comprises 30%-60% solute by weight). After dissolving the elastomer in the solvent, the solution is poured over a form, which may be a plate (e.g. the bottom surface of a mould). The solvent is evaporated over time to form the substrate. In some embodiments, the solvent is evaporated over a period of at least 48 hours. In some embodiments, the solute is dissolved in the solvent for a period of at least 48 hours before the solution is poured over the form. After enough of the solvent has evaporated the substrate may be peeled off of the form for further processing. The substrate is typically cast to a thickness which is in the range of about 1 mm to about 2 mm although this is not necessary.

In some embodiments, the substrate is prepared in block 110 by heat pressing a solid elastomer. Heat pressing involves pressing the solid elastomer between a pair of plates that are maintained at an elevated temperature (e.g. above 120° C.). Heat pressing can in some cases allow the substrate to be prepared expeditiously (i.e. within ten minutes or less). The substrate may, for example, be heat pressed to a thickness which is typically in the range of about 1 mm to 1.5 mm. Preferably the heat pressed substrate is cooled before it is peeled off from the heat press for further processing. In some embodiments the heat pressed substrate is allowed to cool to a temperature that is at or near room temperature (e.g. 20° C.) before it is removed from the heat press.

In some embodiments, the substrate is prepared in block 110 by injection moulding.

The substrate preparation methods listed above are not exhaustive. A substrate may be made using any suitable technology. Examples of other potentially suitable technologies include, but are not limited to: spin casting, doctor blading, injection molding, 3D printing, etc.

In some embodiments, preparation of the elastomeric substrate in block 110 comprises making the elastomeric substrate in a way which limits the elasticity, bendability and/or stretchability of the elastomeric substrate at certain areas of the substrate (e.g. the substrate may comprise areas which facilitate more stretch and areas which facilitate less stretch). For example, preparation of the elastomeric substrate in block 110 may involve embedding a higher strength material such as copper (e.g. copper foils having a wave-like pattern, coiled springs of copper, etc.) or a less elastic plastic material in certain areas of the substrate and/or casting the substrate to be thicker at certain areas. In some embodiments, areas of the elastomeric substrate which support attached electronic components are made to facilitate less stretch. In some embodiments, areas which support traces which extend over a distance are made to facilitate more stretch.

In block 115, a surface of the elastomeric substrate is roughened. Roughening the substrate surface increases the surface energy of the substrate. Increasing the surface energy of the substrate can advantageously improve the adhesion characteristics of the substrate at the roughened surface.

In some embodiments, roughening the substrate surface in block 115 involves mechanically abrading (e.g. sanding, sand blasting, etc.) a surface of the substrate after the substrate is prepared in block 110.

In some embodiments, the substrate surface is roughened in block 115 during the substrate preparation step of block 110. For example, where the substrate is prepared by solvent casting in block 110, the substrate may be cast on a plate having a macroscopically rough surface (e.g. a sandblasted surface made of glass or other suitable material). This can cause the surface of the substrate that is formed in contact with the roughened surface of the plate to have a corresponding roughness. Where the substrate is prepared by heat pressing in block 110, at least one of the heat press plates may have a macroscopically rough surface to introduce roughness on the surface of the substrate contacting the rough surface of the plate as the elastomer is pressed between the heat press plates. A macroscopically rough surface may in some cases refer to a surface comprising dimples and/or hills having a diameter in the range of about 100 um to about 1 mm. In some embodiments, the depth and/or width of the dimples/hills on a macroscopically rough surface are uniform across the macroscopically rough surface (e.g. the differences in the depth and/or widths of the dimples/hills exceed no more than about 20 um).

In optional block 116, via holes are created at select locations on the elastomeric substrate. Block 116 may, for example be performed for the purposes of fabricating multi-layered stretchable circuit boards as described elsewhere herein.

Block 116 comprises first identifying the locations of the vias (e.g. based on a circuit layout). After the locations of the vias are identified, block 116 comprises creating one or more holes which extend through the elastomeric substrate (i.e. between opposing surfaces of the elastomeric substrate) at the locations of the vias. The via holes may be created using any suitable technology. In some embodiments, the via holes are created by power drilling (e.g. using a high speed drilling machine). In some embodiments, the via holes are created by thermal drilling (e.g. using the tip of a soldering iron), laser cutting or waterjet cutting.

After creating the via holes, block 116 optionally comprises applying a layer of adhesive material to edges of the via holes. For example, block 116 may involve applying a layer of epoxy to the edges of the via holes. In some embodiments, the epoxy contains silver. Applying a layer of adhesive to the edges of the via holes can in some cases help promote adhesion of an electrically conductive material to the edges of the via holes when the electrically conductive material is electrolessly deposited on the substrate in block 160.

In block 120 the elastomeric substrate is stretched and mechanically maintained in a stretched state (i.e. pre-stretched). For example, the stretched elastomeric substrate may be kept stretched by affixing the stretched substrate to a base which is usually made of a rigid material. The stretched substrate may be affixed to the base by clips or the like. For example, the substrate may be stretched to its stretched state and affixed to a glass slide by metal clips. Although not necessary, the elastomeric substrate may be stretched immediately after the substrate is roughened in block 115.

In some embodiments the substrate is uniaxially stretched and affixed. In these embodiments, the stretched substrate may have a strain in the uniaxial direction which is typically in the range of about 0.2 to 0.4 (i.e. the stretched length is 1.2 to 1.4 times the unstretched length measured in a direction along the axis of stretch). It may be desirable to stretch the substrate in a single direction (instead of multiple directions) in some cases to simplify the fabrication process and/or avoid the need to use customized frames to stretch the substrate in multiple directions.

In some embodiments, the substrate is uniaxially stretched in a longitudinal direction (i.e. in a lengthwise direction along the longest side of a rectangular substrate). In other embodiments, the substrate is uniaxially stretched in a transverse direction (i.e. in a widthwise direction along a short side of a rectangular substrate).

In some embodiments, the substrate is stretched in each of two or more directions simultaneously and then maintained in its stretched state. In these embodiments, the substrate in its stretched state may span a surface area which is significantly greater than the surface area spanned by the substrate in its normal un-stretched state (e.g. greater by 5%, 10%, 20%, 25% or more). It may be desirable to pre-stretch the substrate in two or more directions (instead of a single direction) to provide a printed circuit board that is stretchable in each of plural directions.

In block 130, the stretched substrate is surface treated to further increase the surface energy of the roughened surface. In a currently preferred embodiment, surface treatment comprises plasma treating the stretched substrate. For example, the roughened surface may be treated in air plasma. The air plasma may cause surface oxidation of the substrate.

Other surface treatment techniques that may be utilized to increase the surface energy of the stretched substrate include, but are not limited to: UV treatments such as UV grafting, laser etching, chemical surface treatments, sequential growth of additional polymer layer(s), surface casting, nanofiller loading, etc. Plasma treatment may in some cases be preferred over these types of surface treatment due to its relatively lower costs and/or environmental footprint.

In some embodiments, after the surface treatment the static water contact angle of the roughened substrate is reduced to less than about 47° (e.g. 45° or less).

In block 140, a catalyst is applied on the treated surface of the stretched substrate. The catalyst may be applied, for example, by contacting the surface of the stretched substrate with a catalyst solution. Preferably the catalyst solution has a viscosity in the range of about 1 to 10 centipoise (e.g. about 5 centipoise). This viscosity range tends to promote adhesion to the surface of the stretched substrate. The catalyst solution is applied on the treated surface and reduced in block 150 to form embedded catalyst particles (e.g. catalyst nanoparticles) on the treated surface. The embedded catalyst particles facilitate reduction of metal ions (e.g. copper ions) on the surface of the substrate (rather than in bulk solution) when the substrate is wetted in an electroless deposition solution in block 160. Since the catalyst particles are embedded on the surface of the substrate, a metal layer will be encouraged to form on the surface of the substrate in block 160.

In some embodiments, the catalyst is silver and the catalyst solution is a silver ink. In some embodiments, the silver ink is a silver nitrate solution such as silver nitrate dissolved in ethanol, ethylene glycol or a mixture of ethanol and/or ethylene glycol.

In some embodiments, the catalyst is palladium and catalyst solution is a solution containing palladium.

In some embodiments, the catalyst is selected based on the material of the substrate. For example, the catalyst may be selected based on its affinity for the material of the substrate.

In some embodiments, the concentration of the catalyst solution is adjusted based on the polarity of the substrate.

In some embodiments, the composition of the solvent which forms part of the catalyst solution is selected based on the material of the substrate. For example, where the substrate is SEBS, a solvent that is a mixture of ethylene glycol and ethanol is advantageously reasonably viscous and wets the SEBS substrate well. As another example, for substrates made of a relatively polar material (e.g. cellulose) the solvent may include more water.

In some embodiments, the catalyst solution is applied on the entire surface of the stretched substrate to encourage catalyst particles to form on the entire surface of the substrate. In other embodiments, the catalyst solution is applied only on select areas of the surface. For example, the catalyst solution may be applied only on areas where electrically conductive material is desired to be deposited in block 160. This can reduce the amount of catalyst solution consumed in cases where it is not necessary by design to deposit electrically conductive material on the entire surface of the substrate in block 160.

The catalyst solution may be selectively applied on the surface of the substrate by techniques such as ink jet printing, screen printing, printing over a mask, etc. In some embodiments, the catalyst solution is applied non-selectively on the substrate and some of the catalyst solution is subsequently removed from certain regions of the substrate (e.g. via laser ablation).

In block 150, the catalyst solution is reduced to form nanoparticles and/or a thin film of the catalyst on the surface of the substrate. In situations where the catalyst solution does not reduce naturally on the substrate (e.g. silver nitrate solution on SEBS), reduction can be achieved by exposing the surface coated with the catalyst solution to plasma where free electrons act as a reducing agent. For example, a silver nitrate catalyst solution may be reduced on SEBS via plasma treatment such as air plasma, argon plasma, nitrogen plasma, etc. As another example, a chemical reducing agent such as stannous chloride may be applied to reduce the catalyst.

In some embodiments, the catalyst solution is reduced with a liquid reducing agent such as a solution of Sn(II) chloride. The solution may be formed by dissolving Sn(II) chloride in hydrochloric acid. In some embodiments, the catalyst is reduced with a salt having a chemical potential higher than the chemical potential of the catalyst solution.

One or more blocking layers may be optionally applied over parts of the substrate to control the reduction of the catalyst in block 150. For example, a blocking layer may shield parts of the substrate from exposure to plasma to discourage the formation of the catalyst on areas of the substrate where electrically conductive material does not need to be deposited in block 160. Examples of suitable blocking layers include self-adhesive layers such as masking tape, customized pre-fabricated masks (e.g. masks made of aluminum, acrylic, etc.) and adherent resists that may be patterned onto the substrate.

In block 160, an electroless deposition solution is applied on the catalyst coated surface. An electroless deposition solution is a solution from which a conductive material (e.g. a metal) can be deposited autocatalytically (i.e. without applying a current). An electroless deposition solution typically comprises a metal salt and a reductant. In block 160, the electroless deposition applied on the catalyst is allowed to react with the catalyst on the substrate to form a layer of electrically conductive material on the surface of the substrate.

Examples of suitable electrically conductive materials include, but are not limited to copper, silver and gold. The conductive material electrolessly deposited on the surface of the substrate in block 160 may, for example, have a thickness which is in the range of about 0.05 μm to about 0.5 μm.

Block 160 typically involves immersing the substrate in a bath containing the electroless deposition solution. Preferably the substrate is immersed in the bath for a controlled period of time to avoid prolonged exposure to the electroless deposition solution. Prolonged exposure to the electroless deposition solution can undesirably result in the evolution of hydrogen gas which can create gas bubbles between the substrate and the deposited material. In some embodiments, the substrate is immersed in the bath for about 15 minutes. In some embodiments, the substrate is immersed in the bath until bubbling in the bath is observed.

In some embodiments, the substrate is rinsed with deionized water immediately after it is removed from the bath containing the electroless deposition solution.

In block 170, a second layer of electrically conductive material is formed on top of the electrolessly deposited layer of electrically conductive material. The second layer of electrically conductive material may for example have a thickness which is in the range of about 1 μm to about 10 μm. In some embodiments, the second layer of electrically conductive material has a thickness of about 3 to 10 times the thickness of the first layer of electrically conductive material.

In some embodiments, the second layer of electrically conductive material comprises the same electrically conductive material as the electrolessly deposited layer of electrically conductive material. In other embodiments, the second layer of electrically conductive material comprises an electrically conductive material which is different from the electrolessly deposited layer of electrically conductive material. For example, a layer of gold may be electrolessly deposited on the substrate in block 160 and a layer of copper may be formed on the electrolessly deposited layer of gold in block 170.

In a currently preferred embodiment, the second layer of electrically conductive material is formed via eletrodeposition. Electrodeposition involves immersing the substrate in an electrodeposition solution and applying an electrical potential between the existing electrically conductive surface of the substrate (i.e. the electrolessly deposited layer of conductive material) and an electrode. The applied potential causes an electrical current to flow through the electrodeposition solution. In some embodiments, the current is in the range of 0.01 A/cm² to 0.1 A/cm² of the area of the substrate onto which the electrically conductive material is being deposited.

In some embodiments, a relatively small electric potential is applied between the conductive surface of the substrate and the electrode to cause a relatively small current (e.g. less than 0.05 A/cm²) to flow through the electrodeposition solution. This can promote diffusion between the Nernst double layer and the electrodeposition solution. Applying a relatively small electric potential can in some cases help to improve uniformity of the second layer of electrically conductive material.

In some embodiments the electrodeposition is continued for about 2 hours to electrodeposit the second layer of electrically conductive material onto the existing electrically conductive surface.

In some embodiments, electrodepositing the second layer of electrically conductive material comprises positioning the electrode at a distance which is relatively far from the substrate. This can encourage the formation of a relatively smooth and/or uniform second layer of electrically conductive material on the substrate.

Where the second layer of electrically conductive material is formed via electrodeposition, the magnitude of the electrodeposition current can be adjusted to control the smoothness of the surface of the conductive material (i.e. a smaller current level results in a smoother finish) and/or the thickness of the conductive material. In some embodiments, the thickness of the electrodeposited material can also be controlled by controlling the duration of time the substrate spends immersed in the electrodeposition solution.

In some embodiments, the substrate is heated after the second layer of electrically conductive material is formed in block 170. For example, the substrate may be heated to a temperature of about 80° C. The heating may be performed in an oven. In some embodiments, the substrate is heated in an environment which is free from oxygen. In some embodiments, the substrate is heated under an inert atmosphere. For example, the substrate may be heated at about 80° C. in argon for up to about 2 hours.

In block 180, the metal-coated substrate is patterned. Patterning may be done using techniques such as photolithography. For example, block 180 may involve laminating a photoresist film onto the metallic layer (e.g. copper layer) of the substrate, followed by overlaying a mask which contains transparent and opaque regions corresponding to a layout of an electric circuit. The masked substrate may subsequently be exposed to UV radiation to cure the unmasked portions of the photoresist film. Portions of the photoresist film (i.e. either the cured portion or the uncured portion depending on whether a positive photoresist or a negative photoresist is used) and corresponding portions of the underlying metal layer are stripped from the substrate to create electrical traces which are arranged on the substrate based on the layout. The remainder of the photoresist film (i.e. portions of the photoresist film covering the electrical traces) is subsequently removed from the substrate.

In some embodiments, removing the uncured portions of the photoresist film comprises treating the laminated substrate with a suitable photoresist removal solution such as an aqueous sodium bicarbonate solution.

In some embodiments, removing the cured portions of the photoresist film comprises treating the laminated substrate with a suitable photoresist removal solution such as an aqueous sodium hydroxide solution.

In some embodiments, removing the underlying metal layer comprises exposing the metal layer to a suitable etchant (e.g. an acid such as ferric acid).

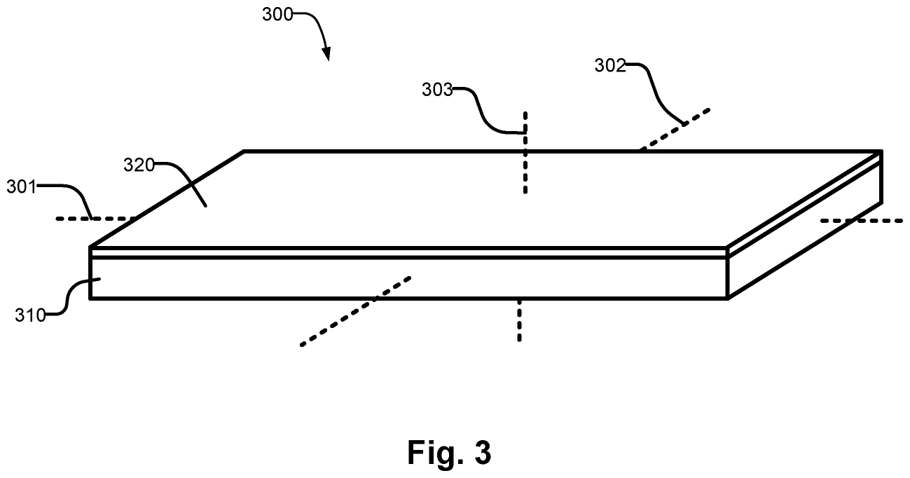

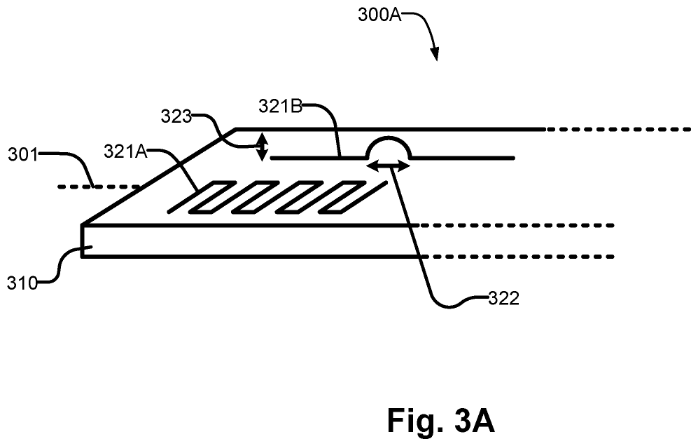

In some embodiments, block 180 involves patterning the substrate to form traces. The traces may be arranged to provide desired electrical interconnections and also to allow the circuit board to be stretched in at least one direction while avoiding damage to the traces. The traces may, for example, have one or more of the following arrangements:
some traces or some segments of a trace are serpentine shaped to meander along a direction in which the substrate is stretched (e.g. see FIG. 3A). With this arrangement, the serpentine bends of the trace are compressed when the substrate is released from its stretch in block 190. The serpentine bends straighten out when the substrate is stretched to improve the electrical reliability of the trace when the substrate is stretched.
some segments of a trace are not adhered to the surface of the substrate. For example, such sections of a trace may be spaced apart from the substrate by a distance of about 0.5 mm to about 2 mm. These elevated sections may have lengths of, for example about 0.5 cm to about 2 cm. With this arrangement, the elevated portions of the trace can flatten out when the substrate is stretched to improve the electrical reliability of the trace when the substrate is stretched. In some embodiments, the elevated traces are formed by ironing the copper to the substrate (instead of heating the copper substrate in an oven) in block 170 and applying less pressure at locations where it is desirable for the traces to become detached from the substrate.

In block 190, the substrate is released from its stretched state after it is patterned in block 180. This may involve detaching the substrate from a base if the substrate was kept stretched by being affixed to a base in block 120.

A printed circuit board fabricated using method 100 (e.g. circuit boards 300, 300A) or having a structure like the structures of circuit boards 300, 300A may advantageously provide one or more of the following:
stretchability (i.e. the ability to stretch without undergoing plastic deformation) along the pre-stretched direction (for example by about 1-5% or more);
a flexural modulus of less than about 5 GPa; and
adhesion of 5 A on the ASTM scale (measured according to ASTM standard D3359-09).

FIG. 1A is a flowchart of a method 100A of fabricating a SEBS-based printed circuit board. Method 100A is an example of one specific way for implementing method 100 for the case where the substrate is SEBS, surface preparation is provided by an air plasma, the catalyst for electroless deposition of copper is provided by a silver ink, and the electroless deposition solution comprises cupric sulphate.

In block 110A a SEBS substrate is prepared. In some embodiments, the SEBS substrate is prepared by solvent casting. Solvent casting of SEBS may involve dissolving commercially available SEBS (e.g. TUFTECH™ 1052 from Asahi Kasei of Tokyo, Japan) in a solvent such as toluene and subsequently pouring the solution over a plate. Preferably the plate is macroscopically roughened. In some embodiments, the solution has 40% w/w concentration (i.e. the solution comprises 40% solute by weight). In some embodiments, the solvent is evaporated for a period of at least 48 hours before the SEBS substrate is peeled off of the roughened plate for further processing.

In other embodiments, the SEBS substrate is prepared by heat pressing SEBS pellets between metal plates. Preferably, at least one of the metal plates has a roughened surface. Heat pressing advantageously allows the SEBS substrate to be prepared within a short period of time. For example, a SEBS substrate can be prepared by heat pressing SEBS pellets at about 176° C. for about four minutes.

In block 120A the SEBS substrate is stretched and mechanically maintained in its stretched state. In a currently preferred embodiment, the SEBS substrate is stretched uniaxially in a lengthwise direction by up to 25% of its original length (i.e. the SEBS substrate has a strain of up to 0.25 when it is in its stretched state).

In block 130A the SEBS substrate is plasma treated to increase the surface energy of the substrate. In some embodiments, the SEBS substrate is plasma treated for about five minutes in air plasma at 180 watts.

In block 140A a silver ink is applied on the surface of the stretched substrate. In some embodiments, the silver ink comprises silver nitrate dissolved in a mixture of ethanol and ethylene glycol. For example, the silver ink may comprise silver nitrate dissolved in a mixture of 2:1 w/w of ethanol and ethylene glycol. In some embodiments, the silver ink comprises a 21 nM solution of silver nitrate.

In block 150A the silver ink is reduced on the SEBS substrate through exposure to air plasma at about 500 mbar for about 30 minutes. The reduction of the silver ink causes absorbed silver rods to form on the surface of the substrate.

In block 160A a thin layer of copper is electrolessly deposited on the silver embedded surface of the SEBS substrate. In some embodiments, the substrate is immersed in an electroless deposition solution containing sodium potassium tartrate, cupric sulfate and formaldehyde. In some embodiments, the molar ratio of potassium tartrate, cupric sulfate, and formaldehyde is 1:1:1.

In some embodiments, the electroless deposition solution may be formed by mixing a first solution comprising sodium potassium tartrate, a second solution comprising cupric sulfate, and a third solution comprising formaldehyde. In a specific non-limiting example embodiment of the invention, the first solution has a composition which is equivalent to dissolving about 8.0 grams of sodium potassium tartrate and about 2.6 grams of sodium hydroxide in about 20 ml of water. In a specific non-limiting example embodiment, the second solution has a composition which is equivalent dissolving 1.4 grams of cupric sulfate pentahydrate in about 20 ml of water.

In block 170A, the thickness of the copper is increased by electrodeposition. In some embodiments, the substrate is immersed in a copper sulfate solution. In some embodiments, a constant current of 0.05 A/cm² is caused to flow between the electrically conductive material on the substrate and a sacrificial electrode for about 2 hours.

In block 180A, the SEBS substrate is patterned using, for example, suitable photolithography techniques as described elsewhere herein.

In block 190A, the SEBS substrate is released from its stretch.

In proof of principle experiments circuit boards were made according to method 100A using SEBS for the substrate. The SEBS was TUFTECH™ 1052 from Asahi Kasei of Tokyo, Japan. This material has a styrene content of about 20% styrene and a medium molecular weight. Measured characteristics of the proof of principle circuit boards include: substrate thickness of about 400 um, substrate area of about 100 cm², maximum strain of about 10% before permanent deformation, and conductive copper layer thickness of about 40 um.

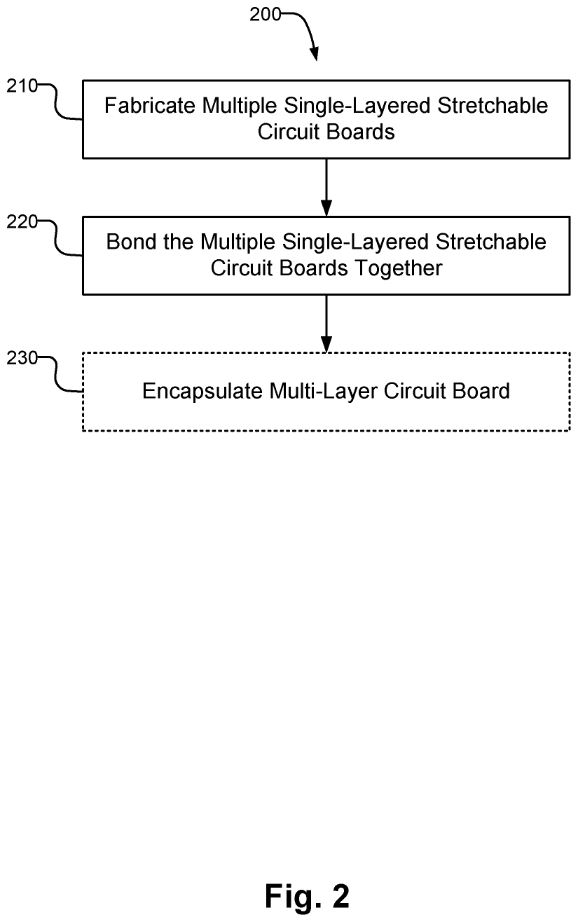

FIG. 2 is a flowchart of an example method 200 of fabricating a multi-layered printed circuit board according to an example embodiment of the invention. In step 210, two or more single-layered printed circuit boards (e.g. circuit board 300) are fabricated using method 100. Step 210 preferably comprises fabricating at least some single-layered printed circuit boards which have via holes. The via holes provide paths that can carry conductors which carry electrical signals between different layers of the multi-layered printed circuit board and may also assist in aligning different layers of the multi-layered circuit board.

In step 220, the single-layered printed circuit boards are bonded to each other by applying suitable adhesives on the substrate of the printed circuit boards. Examples of suitable adhesives include, but are not limited to, conductive epoxy and solder. In some embodiments, the material of the adhesive is selected based on the material of the substrate of the printed circuit boards. For example, printed circuit boards comprising a SEBS substrate may be bonded to each other using compatible adhesives (e.g. a SEBS hot melt adhesive).

Method 200 may optionally comprise an encapsulation step 230 in some embodiments. Step 230 comprises encapsulating the multi-layered printed circuit board in a suitable resin. Encapsulating the circuit board can in some cases advantageously improve the electrical insulating characteristics of the multi-layered printed circuit board.

FIG. 3 is a schematic perspective view of a pre-patterned circuit board 300 of a type which may be fabricated using method 100 according to an example embodiment. As depicted in FIG. 3, circuit board 300 comprises an electrically conductive layer 320 deposited on top of an elastomeric substrate 310. Circuit board 300 is advantageously stretchable along a longitudinal axis 301 or a transverse axis 302 or both. For example, circuit board 300 may be stretchable along longitudinal axis 301 by 5% or more without undergoing plastic deformation and/or stretchable along transverse axis 302 by 5% or more without undergoing plastic deformation. Circuit board 300 may also, for example, be stretchable along longitudinal axis 301 by 25% or more and/or stretchable along transverse axis 302 by 25% or more after undergoing plastic deformation.

In some embodiments, circuit board 300 has a modulus of elasticity of less than about 10 GPa (e.g. less than about 5 GPa, 1 GPa, or 0.5 GPa) when stretched along the longitudinal axis 301 and/or when stretched along the transverse axis 302.

In some embodiments, circuit board 300 is flexible in addition to being stretchable. In these embodiments, circuit board 300 is bendable around one or more of longitudinal axis 301, transverse axis 302 and vertical axis 303. For example, circuit board 300 may have a flexural modulus of less than about 5 GPa (e.g. less than about 2 GPa, 1 GPa, 0.5 GPa or 0.1 GPa) when bent around the longitudinal axis 301, a transverse axis 302 and/or a vertical axis 303.

FIG. 3A is a schematic perspective view of a section of a patterned circuit board 300A of a type which may be fabricated using method 100 according to an example embodiment. As depicted in FIG. 3A, conductive layer 320 has been etched into traces 321 corresponding to a layout (not shown) of circuit board 300A.

In some embodiments, circuit board 300A comprises traces 321A or segments of traces 321A which are serpentine shaped. Serpentine traces 321A meander along a direction in which circuit board 300A is stretchable. For example, circuit board 300A may be stretchable along longitudinal axis 301 and serpentine traces 321A may meander along the same longitudinal axis 301 as shown in FIG. 3A. Serpentine traces 321A may comprise rectangular corners as shown in FIG. 3A, or other crenulated shapes such as zig zags, sinusoidal shapes, etc. When circuit board 300A is stretched, bends in serpentine traces 321A straighten out to accommodate the extension of circuit board 300A caused by the stretch.

In embodiments where circuit board 300A is stretchable in multiple directions, serpentine traces 321A may be laid out on circuit board 300A to meander along a direction in which circuit board 300A is the most stretchable.

In some embodiments, circuit board 300A comprises traces 321B which have segments that are lifted off from the surface of circuit board 300A as shown in FIG. 3A. These segments are lifted off of the surface of circuit board 300A across a distance 322 which is typically in the range of about 0.5 cm to about 2.0 cm and to a height 323 of up to about 0.5 mm to about 2.0 mm. Preferably the distance 322 across which traces 321B are lifted off from the surface of circuit board 300A extend along a direction in which circuit board 300A is stretchable. For example, circuit board 300A may be stretchable along longitudinal axis 301 and traces 321B may segments which are lifted off across a distance 322 along longitudinal axis 301 (e.g. see FIG. 3A). When circuit board 300A is stretched, the lifted off segments of traces 321B are flattened to accommodate the extension of circuit board 300A caused by the stretch.

As described elsewhere herein, traces 321B may be fabricated by applying different levels of heat and/or pressure at different regions of the substrate when it is heated in step 170. Traces located at regions which receive less heat and/or pressure during step 170 may lift off from the substrate when the substrate is released from its stretch in step 190.

Traces 321A, 321B can advantageously improve the electrical reliability of circuit board 300A when circuit board 300A is stretched.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are consistent with the broadest interpretation of the specification as a whole.

1. A method for fabricating a circuit board, the method comprising:
providing a substrate made of an elastomeric material and having a roughened surface;
stretching the elastomeric substrate to a stretched state;
holding the elastomeric substrate in the stretched state;
increasing the substrate's surface energy by applying a surface treatment to the roughened surface of the substrate;
depositing a catalyst on the roughened surface of the substrate;
depositing a first layer of electrically conductive material on the roughened surface of the substrate by applying an electroless deposition solution to the roughened surface of the substrate;
electrodepositing a second layer of electrically conductive material on the first layer of electrically conductive material; and
releasing the elastomeric substrate from the stretched state.

2. The method according to claim 1 wherein providing the elastomeric substrate comprises:
dissolving styrene-ethelyne-butylene-styrene (SEBS) in a solvent to produce an elastomeric solution;
pouring the elastomeric solution over a coarse surface; and
evaporating the solvent from the elastomeric solution to form the elastomeric substrate.

3. The method according to claim 2 wherein the elastomeric solution has a concentration in the range of 35% w/w to 45% w/w.

4. The method according to claim 1 wherein providing the polymeric substrate comprises pressing styrene-ethelyne-butylene-styrene (SEBS) pellets between first and second heated plates.

5. The method according to claim 1 wherein stretching the elastomeric substrate comprises stretching the substrate by at least 10% in a longitudinal direction.

6. The method according to claim 1 wherein the surface treatment applied to the substrate comprises plasma treating the roughened surface of the substrate.

7. The method according to claim 1 wherein after the surface treatment a contact angle of water on the roughened surface is less than 47 degrees.

8. The method according to claim 1 wherein depositing the catalyst on the roughened surface of the substrate comprises applying a catalyst to the roughened surface of the substrate and reducing the catalyst on the substrate to yield particles of the catalyst on the roughened surface of the substrate.

9. The method according to claim 8 wherein the catalyst is applied in a catalyst solution.

10. The method according to claim 9 wherein the catalyst solution is a silver ink.

11. The method according to claim 10 wherein the silver ink comprises a solvent selected from ethanol, ethylene glycol and a mixture of ethanol and ethylene glycol.

12. The method according to claim 10 wherein the silver ink comprises silver nitrate dissolved in a mixture of 2:1 w/w of ethanol and ethylene glycol.

13. The method according to claim 10 wherein the silver ink comprises a solution of silver nitrate having a concentration in the range of 15 to 26 nM.

14. The method according to claim 8 wherein reducing the catalyst comprises exposing the catalyst to an air plasma.

15. The method according to claim 14 wherein exposing the catalyst to the air plasma is performed at a pressure in the range of 300 to 800 mbar.

16. The method according to claim 14 wherein exposing the catalyst to the air plasma is performed for at least 15 minutes.

17. The method according to claim 1 wherein the electroless deposition solution comprises a cupric sulfate solution.

18. The method according to claim 17 wherein the cupric sulfate solution further comprises sodium potassium tartrate and formaldehyde.

19. The method according to claim 18 wherein the electroless deposition solution comprises a potassium tartrate solution, the cupric sulfate solution, and a formaldehyde solution in a ratio of 1:1:1.

20. The method according to claim 1 comprising immersing the substrate in the electroless deposition solution for a period of 15 minutes or less.

21. The method according to claim 1 comprising rinsing the substrate in deionized water after removing the substrate from the electroless deposition solution.

22. The method according to claim 1 further comprising heating the substrate under an inert gas atmosphere after electrodepositing the second layer of electrically conductive material.

23. The method according to claim 1 further comprising patterning the first and second layers of electrically conductive material after electrodepositing the second layer of electrically conductive material.

24. The method according to claim 23 wherein patterning the first and second layers of electrically conductive material comprises creating electrically conductive traces arranged in a serpentine shape.

25. The method according to claim 24 wherein the electrically conductive traces are arranged in the serpentine shape to meander along a direction in which the substrate is stretched.

26. The method according to claim 1 further comprising creating one or more via holes on the substrate before stretching the substrate.

27. A method for fabricating a multi-layered circuit board, the method comprising:
fabricating a plurality of single-layered circuit boards according to the method of claim 1; and
bonding the plurality of single-layered circuit boards together to create the multi-layered circuit board.

28. A method according to claim 27 further comprising encapsulating the multi-layered circuit board in a resin.

29-30. (canceled)
